(19) United States
(12) Patent Application Publication
(10) Pub. No.: US 2024/0321605 A1
(43) Pub. Date: Sep. 26, 2024

(54) SEMICONDUCTOR PROCESSING APPARATUS AND METHODS FOR CALIBRATING A SEMICONDUCTOR PROCESSING APPARATUS

(71) Applicant: ASM IP Holding B.V., Almere (NL)

(72) Inventors: Shiva Rajavelu, Tempe, AZ (US); John Tolle, Gilbert, AZ (US); Rich McCartney, Phoenix, AZ (US)

(21) Appl. No.: 18/678,219

(22) Filed: May 30, 2024

Related U.S. Application Data
(63) Continuation of application No. 15/962,980, filed on Apr. 25, 2018, now Pat. No. 12,040,200.
(60) Provisional application No. 62/522,550, filed on Jun. 20, 2017.

(51) Int. Cl. H01L 21/67; C23C 16/458; C23C 16/46; C30B 25/10

(52) U.S. Cl. CPC H01L 21/67115; C30B 25/10; C30B 25/105; H01L 21/67098; H01L 21/67248; C23C 16/4583; C23C 16/46

(57) ABSTRACT

A semiconductor processing apparatus is disclosed that may include a reaction chamber joined by an upstream inlet flange and a downstream outlet flange wherein a longitudinal direction of the chamber extends from the inlet flange to the outlet flange and a plurality of ribs are provided on an outer surface of at least an upper chamber wall. The semiconductor processing apparatus may also include at least one array of heating elements disposed above the reaction chamber and at least one variable positioning device coupled to the at least one array of heating elements and configured to controllably adjust the position of the at least one array of heating elements relative to the position of the plurality of ribs.

### CROSS-REFERENCE TO RELATED APPLICATIONS

This application is a continuation of, and claims priority to and the benefit of, U.S. patent application Ser. No. 15/962,980, filed Apr. 25, 2018 and entitled “SEMICONDUCTOR PROCESSING APPARATUS AND METHODS FOR CALIBRATING A SEMICONDUCTOR PROCESSING APPARATUS,” which is a nonprovisional of, and claims priority to and the benefit of, U.S. Provisional Patent Application No. 62/522,550, filed on Jun. 20, 2017 and entitled “SEMICONDUCTOR PROCESSING APPARATUS AND METHODS FOR CALIBRATING A SEMICONDUCTOR PROCESSING APPARATUS,” which are hereby incorporated by reference herein.

### FIELD OF INVENTION

The present disclosure generally relates to a semiconductor processing apparatus and methods for calibrating a semiconductor processing apparatus.

### BACKGROUND OF THE DISCLOSURE

High-temperature reaction chambers may be used for depositing various material layers onto semiconductor substrates. A semiconductor substrate, such as, for example, a silicon substrate, may be placed on a substrate support inside a reaction chamber. Both the substrate and the support may be heated to a desired set point temperature. In an example substrate treatment process, reactant gases may be passed over a heated substrate, causing the chemical vapor deposition (CVD) of a thin layer of the reactant material onto the substrate. Throughout subsequent depositions, doping, lithography, etch and other processes, these layer are made into integrated circuits.

Various process parameters may be carefully controlled to ensure the high quality of the deposited layers. An example of one such process parameter is the substrate temperature uniformity. During CVD, for example, the deposition gases may react within particular prescribed temperature ranges for deposition onto the substrate. A change in temperature uniformity across a substrate may result in a change in the deposition rate and an undesirable layer thickness non-uniformity. Accordingly, it is important to accurately control the substrate temperature uniformity to bring the substrate to the desired temperature and temperature uniformity before the treatment begins and to maintain the desired temperature and uniformity throughout the process.

In certain applications, the pressure within a reaction chamber, such as a quartz reaction chamber configured for CVD, may be reduced to levels much lower that the surrounding ambient pressure. In such reduced pressure applications the quartz reaction chamber may comprise a cylindrical or spherical chamber since the curved surfaces of such quartz reaction chambers may be better suited to withstand the inwardly directed force resulting from the reduced pressure process. However, when positioning a flat substrate for chemical vapor deposition purposes, where the deposition gases flow parallel to the substrate, it may be desirable that the chamber walls be parallel to the flat surface of the substrate, to obtain uniform deposition on the substrate surface. Uniform deposition may be critical to obtain a high yield of acceptable products to be fabricated from such substrates. However, a quartz reaction chamber comprising flat chamber walls may collapse inwardly when processes comprise reduced pressures when compared with an outwardly convex chamber wall of similar size and thickness.

To handle the inwardly directed forces on a flat chamber wall, gussets or ribs may be provided on the exterior of the walls extending generally perpendicular to the wall to which they are joined, as may be seen in U.S. Pat. No. 4,920,918, issued on May 1, 1990, titled PRESSURE RESISTANT THERMAL REACTOR SYSTEM FOR SEMICONDUCTOR PROCESSING, all of which is hereby incorporated by reference and made a part of this specification. One disadvantage of such a quartz reaction chamber design is that even though quartz is substantially transparent to the radiant lamp energy, provided by radiant lamp heaters, the rib sections present a region of much thicker quartz and may refract the lamp energy to a great extent compared to the flat chamber walls thereby attenuating the lamp energy reaching certain sections of the substrate within the reaction chamber. This attenuation of energy causes cooler regions (i.e., shadows) on the substrate. Such non-uniformity of temperature on the substrate surface reduces the quality of the films that may be deposited, particularly for process conditions that are temperature-sensitive.

Nominally identical CVD tools utilized for wafer deposition may comprise some variance from tool to tool. For example, the reaction chambers utilized in CVD processes may each have a characteristic thermal environment which may, in turn, affect the wafer temperature during a deposition process. The reaction chamber may be fabricated from quartz materials and processes utilized in the fabrication and reworking of the quartz reaction chamber may result in variation in the features of the quartz reaction chamber, such as, for example, critical dimensions, materials quality, refractive properties, etc. In addition, the components within and surrounding the reaction chamber may vary in position and optimal function adding additional variance. The variation in the reaction chambers may be undesirable for high volume manufacturing where multiple reaction chambers may perform the same process recipe with the expectation that the process results are essentially the same. For example, for a CVD process, the resulting deposited layers are expected to possess uniform thickness, carrier mobility, refractive indices, stress, etc.

To overcome the problems, which may arise due to variation in CVD tools, systems and processes known as “tool-to-tool matching” may be employed. However, existing “tool-to-tool matching” systems and processes may be limited, time consuming, cost prohibitive and may not provide effective methods of thermally calibrating multiple chemical vapor deposition systems.

### SUMMARY OF THE DISCLOSURE

In accordance with at least one embodiment of the disclosure, a semiconductor processing apparatus is disclosed. The semiconductor processing apparatus may comprise: a reaction chamber comprising; an upper chamber wall and a lower chamber wall connected by vertical sidewalls, the chamber walls being joined by an upstream inlet flange and a downstream outlet flange wherein a longitudinal direction of the chamber extends from the inlet flange to the outlet flange. The reaction chamber may further comprise a plurality of ribs provided on an outer surface of at least the upper chamber wall, the plurality of ribs being orientated transversely to the longitudinal direction of the chamber. The semiconductor processing apparatus may also comprise: at least one array of heating elements disposed above the reaction chamber and at least one variable positioning device coupled to the at least one array of heating elements and configured to controllably adjust the position of the at least one array of heating elements relative to the position of the plurality of ribs.

The current disclosure may also comprise a method of calibrating a semiconductor processing apparatus and the method may comprise: providing a reaction chamber comprising; an upper chamber wall and a lower chamber wall connected by vertical sidewalls, the chamber walls being joined by an upstream inlet flange and a downstream outlet flange wherein a longitudinal direction of the chamber extends from the inlet flange to the outlet flange. Providing a reaction chamber may further comprise; providing a plurality of ribs provided on an outer surface of at least the upper chamber wall, the plurality of ribs being orientated transversely to the longitudinal direction of the chamber. The method of calibrating a semiconductor processing apparatus may further comprise: providing at least one array of heating elements disposed above the reaction chamber and adjusting at least one variable positioning device coupled to the at least one array of heating elements to controllably adjust the position of the array of heating elements relative to the position of the plurality of ribs.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawing, in which:

FIG. 1 is a perspective view of a semiconductor reaction chamber having a plurality of ribs on the exterior surfaces of the chamber as may be utilized in a semiconductor processing apparatus of the current disclosure;

FIG. 2 is a cross-sectional schematic illustration of portions of a semiconductor processing apparatus of the current disclose;

FIG. 3A is a plan view of an upper heating housing, including an array of heating elements, disposed over a reaction chamber, the array of heating elements being disposed substantially parallel to the longitudinal direction of the reaction chamber;

FIG. 3B is a plan view of an upper heating housing, including an array of heating elements, disposed above a reaction chamber, the array of heating elements being disposed substantially perpendicular to the longitudinal direction of the reaction chamber;

FIG. 4 is a cut-away cross sectional view of a portion of the semiconductor processing apparatus of the current disclosure;

FIG. 5 is schematic illustration of an example upper heating housing as disclosed in the embodiments of the disclosure;

FIG. 6 is an example exploded schematic illustration of portions of the internal configuration of the upper heating housing of the current disclosure; and

FIG. 7 is a perspective view of a semiconductor processing apparatus of the current disclosure illustrating the upper heating housing in the open position.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit or a film may be formed.

The embodiments of the disclosure may include a semiconductor processing apparatus and a particular semiconductor processing apparatus configured for chemical vapor deposition processes. The semiconductor processing apparatus of the current disclosure may comprise a quartz reaction chamber which may operate at reduced pressure and may therefore comprise a plurality of ribs which strengthen the reaction chamber and prevent unwanted implosion when operating at reduced pressure. The semiconductor processing apparatus of the present disclosure may allow for increased control of the temperature uniformity and the thermal environment within the quartz reaction chamber by providing one or more variable positioning devices that are configured for controllably adjusting the position of an array of heating elements relative to the position of the plurality of ribs comprising the quartz reaction chamber. The ability to controllably position and reposition the array of heating elements relative to the plurality of ribs making up the quartz reaction chamber allows for the thermal calibration of a semiconductor processing apparatus and the thermal matching of multiple semiconductor processing apparatus, as well as allowing for an improved temperature uniformity difference across the upper surface of at least one substrate provided within the quartz reaction chamber.

In particular embodiments of the disclosure, the quartz reaction chamber provided for the chemical vapor deposition process may comprise a quartz reaction chamber which has undergone a refurbishment process. In greater detail, once a quartz reaction chamber has been utilized multiple times for chemical vapor deposition processes, it may require processing to restore the quartz reaction chamber back to its original state (or as close as possible to its original state). The processes utilized in restoring the quartz reaction chambers are commonly referred to as “refurbishment processes” and may include, but are not limited to, thermal processing and chemical processing. For example, a quartz reaction chamber refurbishment process may comprise a “fire polishing” process to eliminate micro cracks in the surface of the quartz reaction chamber and in addition the quartz reaction chamber may also be annealed in a high temperature oven (e.g., 1100° C.) to relieve stress in the quartz reaction chamber. Although the refurbishment of quartz reaction chambers enables the quartz reaction chambers to be utilized and reutilized for extended periods of time, the refurbishment process may also alter the critical dimensions of the quartz reaction chamber, which in turn may alter the relative position of an array of heating elements positioned above the quartz reaction chamber during a chemical vapor deposition process. The semiconductor processing apparatus and methods of the current disclosure enable the use of refurbished quartz reaction chambers without degradation in the thermal characteristics, i.e., the thermal uniformity, of the quartz reaction chamber and associated chamber elements.

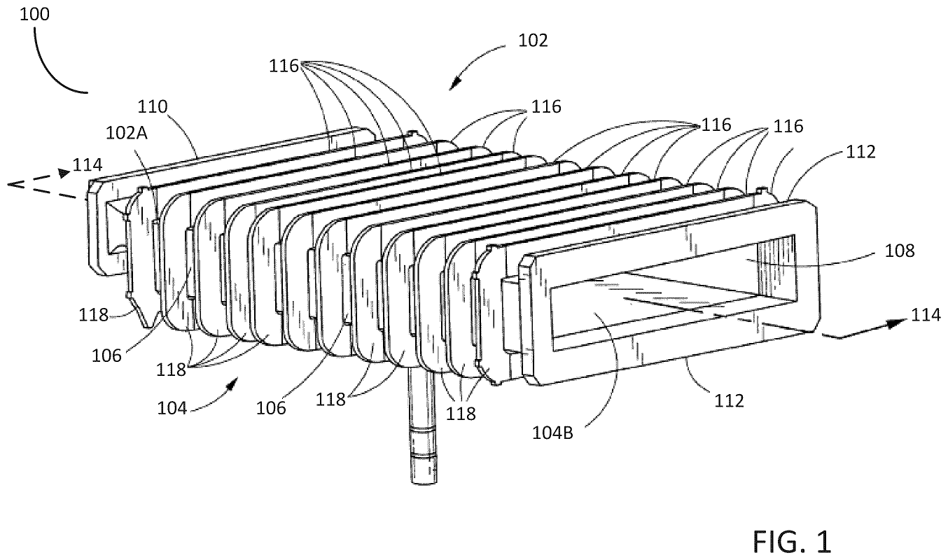

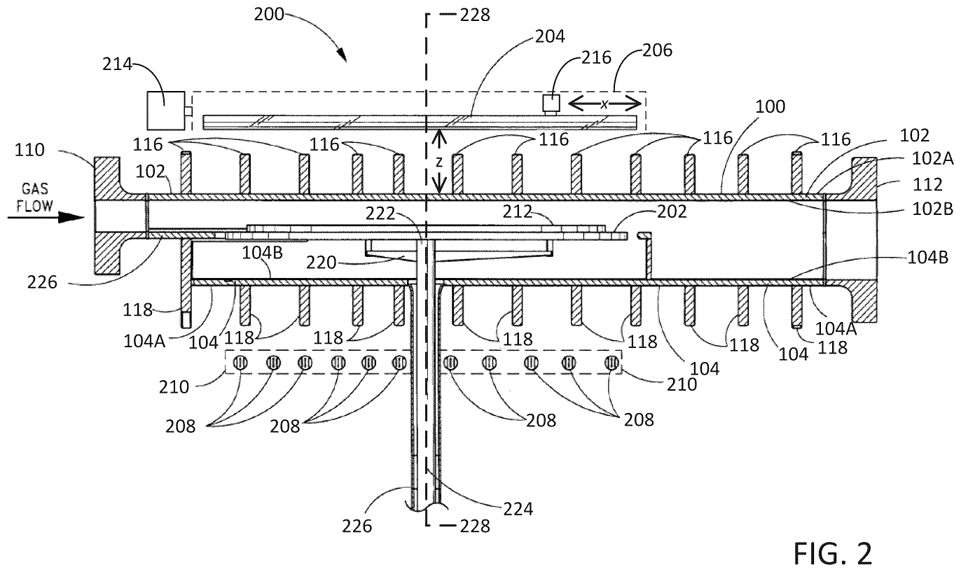

FIG. 1 illustrates a non-limiting example embodiment of a reaction chamber 100 that may be utilized for reduced pressure chemical vapor deposition processes. The reaction chamber 100 may be utilized as part of the semiconductor processing apparatus 200 (of FIG. 2) of the current disclosure. With reference to FIG. 1 and FIG. 2, the reaction chamber 100 may comprise an elongated, generally flattened configuration. The non-limiting example reaction chamber 100 of FIG. 1 may comprise an upper wall 102 with an outer surface 102A and an inner surface 102B, and a lower wall 104A with an outer surface and an inner surface 104B. The upper chamber 102 and the lower chamber wall 104 are connected by vertical side walls 106 and 108. The chamber walls 102, 104, 106 and 108 may be joined by an upstream inlet flange 110 and a downstream outlet flange 112. Upstream and downstream relate to the direction of process gas flow through the reaction chamber 100 and are synonymous in the present disclosure with front and rear, as well as with frontward and rearward.

Alternatively, the reaction chamber 100 may have configurations other than the flattened configuration illustrated in FIG. 1. For example, the reaction chamber 100 may have a tent-shaped cross sectional shape, wherein the upper wall 102 and/or the lower wall 104 have a peak. In another embodiment, the upper/lower walls 102 and 104 may be rounded, giving the reaction chamber 100 a generally ovoid cross-sectional shape. It will be appreciated that in other embodiments, the upper/lower walls 102 and 104 of the reaction chamber 100 can be formed having other shapes in addition to the shapes discussed above, as well as combinations thereof.

In some embodiments, the reaction chamber height is less than the reaction chamber width. In this respect a longitudinal direction for the reaction chamber 100 extends from the inlet flange 110 to the outlet flange 112, or along the section line 114-114. A lateral direction extends between the sidewalls 106 and 108, or transversely to section line 114-114. The height direction is perpendicular to both the longitudinal and lateral axes. In some embodiments of the disclosure the reaction chamber 100 has a length of about 760 mm, a width of about 490 mm, and a height of about 160 mm.

In some embodiments, both the upper wall 102 and the lower wall 104 comprise thin, flat plate-like elements having a rectangular shape. A plurality of ribs 116 extend from the outer surface 102A of the upper wall 102, and a plurality of ribs 118 extend from the outer surface 104A of the lower wall 104. All of the ribs 116 and 118 are oriented lengthwise transversely to the section line 114-114 of FIG. 1, orientated transversely to the longitudinal direction of reaction chamber 100. As shown in FIG. 2, each of the ribs 116 may be positioned directly above and aligned with a corresponding one of the ribs 118. Thus the ribs 116 and 118 comprise pairs of upper and lower ribs. In some embodiments illustrated in FIG. 1 and FIG. 2, twelve pairs of ribs are utilized with approximately eight pairs of ribs being provided above and below the susceptor 202 disposed within reaction chamber 100 (of FIG. 2). In other embodiments, however, greater or fewer pairs of ribs may be used depending on the desired structural integrity of the reaction chamber 100. In some embodiments of the disclosure, corresponding pairs of the upper ribs 116 and the lower ribs 118 may not be aligned with one another. Thus, the upper ribs 116 and the lower ribs 118 may be advantageously be fused to the reaction chamber with different orientations, alignments and/or spacing between the adjacent ribs depending on the desired level of structural integrity of the reaction chamber 100.

FIG. 2 illustrates a cross-sectional view of a semiconductor processing apparatus 200, including the semiconductor reaction chamber 100 of FIG. 1, and illustrates at least one array of heating elements 204 disposed above the reaction chamber 100. In some embodiments of the disclosure, the at least one array of heating elements 204 may comprise an upper heating array and may be housed in an upper heating housing 206 (as illustrated in FIG. 2 by dashed line 100). The semiconductor processing apparatus 200 of FIG. 2 may also comprise an additional array of heating elements 208 disposed beneath the reaction chamber 100 and housed in lower heating housing 210. The additional array of heating elements 208 disposed beneath the reaction chamber 100 may be substantially the same as the array of heating element 204 disposed above the reaction chamber 100.

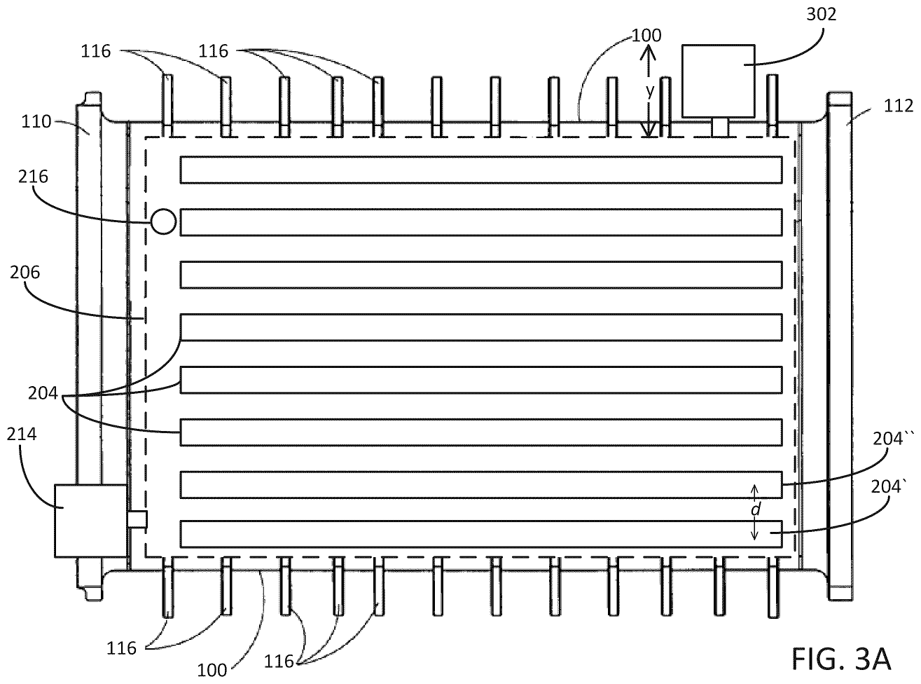

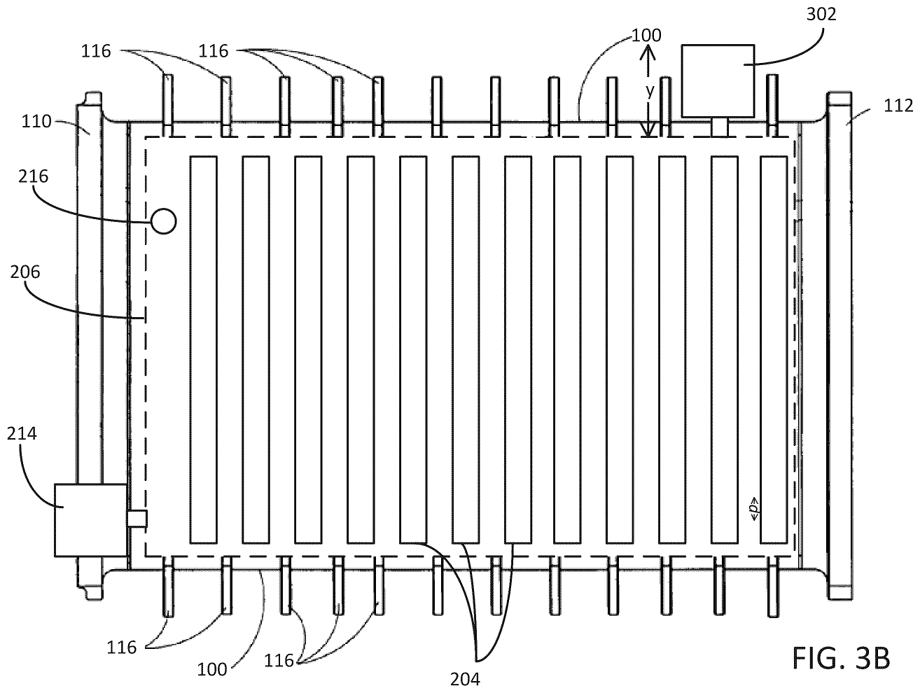

In some embodiments, the at least one array of heating elements 204 disposed above the reaction chamber 100 may comprise a plurality of radiant heating lamps. As a non-limiting example embodiment of the semiconductor apparatus of the current disclosure, FIG. 3A schematically illustrates a plan view of the reaction chamber 100 comprising a plurality of ribs 116, inlet flange 110 and outlet flange 112. FIG. 3A also illustrates the upper heating housing 206, disposed above the reaction chamber 100, and comprising the array of heating elements 204. In some embodiments the plurality of radiant heating lamps 204 comprises a plurality of elongated tube type lamps, spaced-apart in a parallel relationship and also substantially parallel with the reactant gas flow path through the underlying reaction chamber 100. In other words, in some embodiments of the disclosure the plurality of radiant heating lamps 204 are of a plurality of elongated tube type lamps disposed substantially parallel to the longitudinal direction of the reaction chamber, i.e., the plurality of radiant heating lamps 204 are orientated substantially perpendicular to the direction of the plurality of ribs 116. In embodiments wherein the upper array of heating elements comprises a plurality of radiant heating lamps disposed substantially parallel to the longitudinal direction of the reaction chamber the lower array of heating elements disposed beneath the reaction chamber may also comprise a plurality of elongated tube type lamps which may be disposed substantially perpendicular to the longitudinal direction of the reaction chamber, i.e., the upper plurality of radiant heating lamps and the lower plurality of radiant heating elements are substantially perpendicular to one another.

As a further non-limiting example embodiment of the semiconductor apparatus of the current disclosure, FIG. 3B schematically illustrates a plan view of reaction chamber 100 comprising a plurality of ribs 116, inlet flange 110 and outlet flange 112. FIG. 3B also illustrates the upper heating housing 206, disposed above the reaction chamber 100, and comprising the array of heating elements 204. In some embodiments, the plurality of radiant heating lamps 204 comprises a plurality of elongated tube type lamps, spaced-apart in a parallel relationship and also substantially perpendicular with the reactant gas flow path through the underlying reaction chamber 100. In other words, in some embodiments of the disclosure the plurality of radiant heating lamps 204 are of an elongated tube type lamps disposed substantially perpendicular to the longitudinal direction of the reaction chamber, i.e., the plurality of radiant heating lamps 204 are orientated substantially parallel to the direction of the plurality of ribs 116. In embodiments wherein the upper array of heating elements comprises a plurality of radiant heating lamps disposed substantially perpendicular to the longitudinal direction of the reaction chamber the lower array of heating elements disposed beneath the reaction chamber may also comprise a plurality of elongated tube type lamps which may be disposed substantially parallel to the longitudinal direction of the reaction chamber, i.e., the upper plurality of radiant heating lamps and the lower plurality of radiant heating elements are substantially perpendicular to one another.

As illustrated in both FIG. 3A and FIG. 3B, the plurality of radiant heating lamps 204 are of an elongated tube type disposed substantially parallel and adjacent to one another. In some embodiments of the disclosure it may be desired to alter the relative position of an individual heating lamp within the array. For example, in some embodiments of the disclosure repositioning an individual radiant heating lamp 204′ may provide a more uniform temperature profile within the reaction chamber 100, therefore the apparatus of the current disclosure allows for the distance between the individual radiant heating lamps to be adjusted. As a non-limiting example embodiment, FIG. 3A illustrates radiant heating lamps 204′ and 204″ substantially parallel to one another and spaced apart from one another by a distance labelled as d. Therefore, in some embodiments of the disclosure the distance d between radiant heating lamps 204′ and 204″ may be increased or decreased depending on the desired thermal profile required within the reaction chamber 100.

The plurality of radiant heating lamps 204 may be of a similar configuration. Each of the elongated tube type heating elements may comprise a high intensity tungsten filament lamp having a transparent quartz envelope containing a halogen gas, such as iodine. The lamps produce radiant heat energy in the form of full-spectrum light, transmitted through the reaction chamber walls, such as upper chamber wall 102, without appreciable absorption. As is known in the art of semiconductor processing equipment, the power of the various radiant heating lamps may be controlled independently or in grouped zones in response to temperature sensors arranged in proximity to a substrate 212 disposed within the reaction chamber 100, as illustrated in FIG. 2.

The plurality of lamps 204 and 208 as illustrated in FIG. 2 and FIGS. 3A and 3B are illustrated without showing a detailed supporting structure. One of skill in the art, however, will readily recognize a number of manners of mounting the lamps relative to the chamber walls, such as upper chamber wall 102. In some embodiments of the disclosure, the at least one array of heating elements 204 disposed above the reaction chamber 100 may be disposed within an upper heating housing 206. The upper heating housing 206 shown in FIG. 2 is of a simplified form and further illustration and discussion of the upper heating housing 206 will be given herein. However, it should be noted that in some embodiments, the upper heating housing 206 may be attached to a reaction chamber housing, which may support the reaction chamber 100.

In some embodiments, each individual radiant heating lamp includes an integrally formed axially extending lug on each of its opposite ends and a suitable connection pin arrangement extending from each of the lugs for receiving connectors provided at the end of electrical conductors.

Referring back to FIG. 2, the at least one array of heating elements 204 disposed above the reaction chamber 100 may be coupled to at least one variable positioning device, configured to controllably adjust the position of the at least one array of heating elements relative to the position of the plurality of ribs. In some embodiments of the disclosure, the at least one array of heating elements is coupled to at least two variable positioning devices, for example, as illustrated in FIG. 2 by the variable positioning devices 214 and 216. In some embodiments, the at least one array of heating elements is coupled to a least three variable positioning devices, for example, as illustrated in FIG. 3A and FIG. 3B by the variable positioning devices 214, 216 and 302.

As shown by non-limiting example semiconductor processing apparatus 200 of FIG. 2, at least one variable positioning device 214 is configured to controllably adjust the position of the at least one array of heating elements 204 in a direction substantially parallel to the longitudinal direction of the reaction chamber 100. In other words, the variable positioning device positions and re-positions the array of radiant heating lamps in an x-axis, as illustrated in FIG. 2. It should be appreciated that the variable positioning device 214 coupled to the at least one array of heating elements 204 may be coupled via the upper heating housing 206 and may include further coupling materials disposed between the variable positioning device 214 and the individual radiant heating lamps 204.

In a further example embodiment, at least one variable positioning device 216 is configured to controllably adjust the position of the height of the at least one array of heating elements 204 relative to the position of the upper chamber wall 102 of reaction chamber 100 and particular related to the susceptor 202 disposed within reaction chamber 100. In other words, the variable positioning device positions and re-positions the array of radiant heating lamps in a z-axis, as illustrated in FIG. 2. It should be appreciated that the variable positioning device 216 coupled to the at least one array of heating elements 204 may be coupled via the upper heating housing 206 and may include further coupling materials disposed between the variable positioning device 216 and the individual radiant heating lamps 204.

In yet a further example embodiment, at least one variable positioning device 302 (of FIG. 3A or 3B) is configured to controllably adjust the position of the at least one array of heating elements 204 in a direction substantially perpendicular to the longitudinal direction of the reaction chamber 100. In other words, the variable positioning device 302 positions and re-positions the array of radiant heating lamps 204 in a y-axis, as illustrated in FIG. 3A. Again, it should be appreciated that the variable positioning device 302 coupled to the at least one array of heating elements 204 may be coupled via the upper heating housing 206 and may include further coupling materials disposed between the variable positioning device 302 and the individual radiant heating lamps 204.

A number of variable positioning devices may be utilized for controllably adjusting the position and height of the at least one array of heating elements, for example, the variable positioning device may comprises at least one of a micrometer (either manual or actuated by a motor), a differential micrometer, or a piezo-electric actuator.

The variable positioning devices of the current disclosure may be configured to provide a desired placement of the at least one array of heating elements in a number of directions. For example, the at least one variable positioning device of the current disclosure may allow for the displacement of the at least one array of heating elements in one or more directions, including, but not limited, parallel to the longitudinal direction of the reaction chamber, perpendicular to the longitudinal direction of the reaction chamber, and may also controllably adjust the height of the at least one array of heating elements relative to the position of the upper chamber wall of the reaction chamber.

In some embodiments of the disclosure, the at least one variable positioning device may be configured to provide a displacement of the least one array of heating elements no greater than approximately 2 centimeter, or no greater than approximately 1 centimeter, or even no greater than approximately 0.5 centimeters. In addition, the at least one variable positioning device may be configured to provide an displacement accuracy of less than 0.1 millimeters, or less than 0.01 millimeters, or even less than 0.001 millimeters.

The semiconductor processing apparatus of the current disclosure may include additional elements. As illustrated in FIG. 2, the semiconductor processing apparatus of the current disclosure may further comprising a substrate support comprising a susceptor 202 disposed within the reaction chamber 100 beneath the at least one array of heating elements 204, the susceptor 202 being configured to support at least one substrate 212, wherein the substrate support comprising the susceptor 202 has a central axis around which the substrate 212 may rotate. The at least one substrate 212 may be supported by a substrate support which may comprise a susceptor 202 which comprises a material opaque to radiant heat energy, such as graphite or silicon carbide, as is known in the art of semiconductor processing equipment. The susceptor 202 and the substrate 212 are held at a desired height within the reaction chamber 100 by a support structure, as shown in FIG. 2. The susceptor 202 may be supported on arms 220 of a suitable support 222 connected to the upper end of a rotatable shaft 224 that extends through a tube 226 depending from the bottom wall of the reaction chamber 104. The susceptor 202 is shown approximately level with the upper surface of a support plate 226. This facilitates positioning the substrate 212 atop the susceptor 202 of the reaction chamber 100. Further details regarding interior chamber support assemblies and other details about a semiconductor processing chamber can be found in U.S. Pat. No. 6,093,252, issued on Jul. 25, 2000, the entirety of which is hereby incorporated by reference and made a part of this specification.

The semiconductor processing apparatus of the current disclosure allows for greater control of the thermal environment within reaction chamber 100. In some embodiments, the at least one array of heating elements is configured to provide a temperature uniformity difference across a surface of the at least one substrate of less than 1.5° C., or configured to provide a temperature uniformity difference across a surface of the at least one substrate of less than 0.5° C., or even configured to provide a temperature uniformity difference across a surface of the at least one substrate of less than 0.25° C. In some embodiments, the at least one substrate may comprise an exposed upper surface upon which a chemical vapor deposition process primarily proceeds. In some embodiments, the at least one substrate may comprise a substrate with a diameter greater than 25 millimeters, or greater than 100 millimeters, or greater than 200 millimeters, or greater than 300 millimeters, or even greater than 450 millimeters.

In some embodiments of the disclosure, the thermal uniformity within the reaction chamber and particularly, the thermal uniformity across the susceptor upon which the substrate(s) is disposed, may be further improved by utilizing one or more reflectors in combination with the array of heating elements disposed above the reaction chamber. In certain embodiments, the one or more reflectors may comprise a single piece reflector, i.e., the reflector may be fabricated from a single piece of material. In some embodiments of the disclosure the single piece reflector may comprise, a plurality of parabolic segments, each of the individual parabolic segments of the plurality being disposed above and adjacent to a radiant heating element. In alternative embodiments, a plurality of non-parabolic segments may be disposed above and adjacent to a radiant heating element.

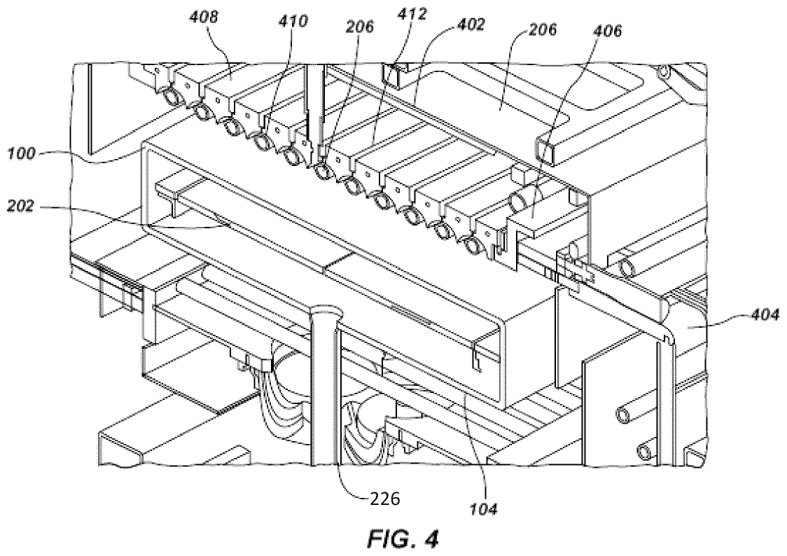

In greater detail, FIG. 4 illustrates a cross section view through reference line 228-228 of the semiconductor processing apparatus 200 of FIG. 2 and provides a detailed view through the reaction chamber 100 and the related components of the semiconductor processing apparatus of the current disclosure. FIG. 4 illustrates the susceptor 202 disposed within the reaction chamber 100 and tube 226 depending from the bottom wall 104 of the reaction chamber 100 through which mechanisms for rotation of susceptor 202 may be provided (not shown). Above the reaction chamber 100 is disposed the upper heating housing 206, illustrated in the closed position, the upper heating housing 206 comprising upper heating housing wall 402 in contact with the reaction chamber housing 404. Disposed within the upper heating housing 206 and coupled to the upper heating housing 206 via bracket 406 is the single piece reflector 408. The single piece reflector 408 comprises a plurality of parabolic segments 410, each of the individual parabolic segments 410 being disposed above and adjacent to an individual radiant heating lamp 206. In some embodiments of the disclosure, each of the radiant heating lamps 206 is located at the focal point of the corresponding parabolic segment associated with that radiant heating lamp such that the radiated heat energy which impinges on the parabolic segment will be reflected down onto the underlying susceptor and the associated substrate(s).

In some embodiments of the disclosure, the one or more variable positioning devices may be configured to provide an adjustable distance between the radiant heating lamps and the single piece reflector and particularly the focal points of the plurality of parabolic segments. Such adjustment in the relative position of the radiant heating elements and the focal points of the plurality of parabolic segments enables that the radiant heating elements are positioned at the focal point of the corresponding parabolic element and such relative positioning may be achieved across multiple deposition systems such that multiple deposition systems are capable of providing substantially the same thermal environment within the reaction chamber. In alternative embodiments, the one or more variable positioning devices, which may adjust the relative height of the array of heating elements disposed above the reaction chamber, may be coupled to both the array of heating elements and the single piece reflector such that any adjustment in the relative height of the array of heating elements maintains the position of the single piece reflector relative to the array of heating elements.

The single piece reflector may also comprise a plurality of openings 412 which extend from the lower surface of the single piece reflector up to the upper surface of the single piece reflector. In some embodiments each individual opening, extending through the single piece reflector, may be disposed within an individual parabolic element and each opening may extend substantially parallel to the focal point of the parabolic element to proximate a peripheral edge of the single piece reflector. The plurality of opening may be utilized to allow air flow from above the reaction chamber 100 to the interior of upper heating housing 206 and such air flow may allow for cooling of the radiant heating elements and the reaction chamber.

In some embodiments of the disclosure the single piece reflector 408 may be manufactured from a single piece of material, such as, for example, a single piece of gold, aluminum, nickel, copper, metallized mylar, or multilayer dielectric materials.

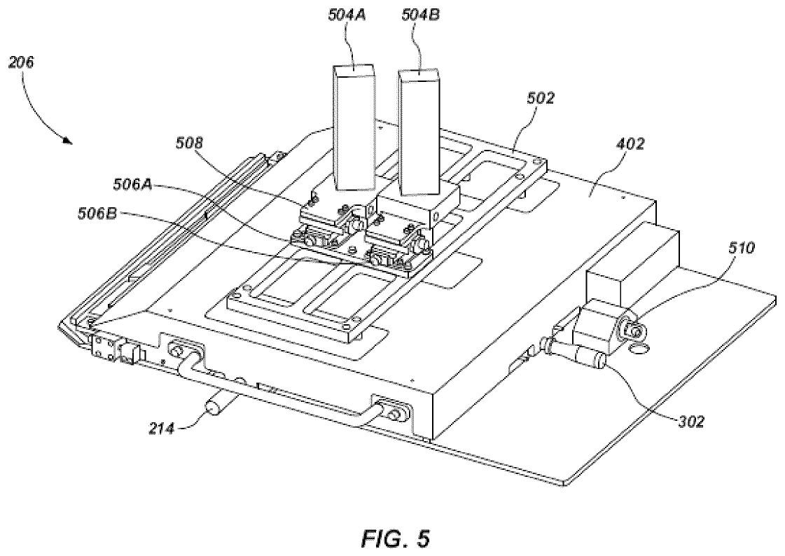

The upper heating housing 206 is shown in more detail in FIG. 5, which illustrates the upper heating housing 206 in the closed (down) position. The upper heating housing 206 may comprise one or more variable positioning devices 214 and 302 which may controllably position and re-position the array of heating elements disposed within upper heating housing 206. In the non-limiting example embodiment illustrated in FIG. 5, the variable positioning devices 214 and 302 may be utilized to adjust the position of the array of heating element in both the x-axis and the y-axis, i.e., parallel and perpendicular to the longitudinal direction of the underlying reaction chamber. The upper heating housing 206 may also comprise upper heating housing wall 402 and coupled to the upper heating housing wall 402 is a pyrometer stand 502 upon which one or more optical pyrometers may be disposed. In the non-limiting example embodiment illustrated in FIG. 5, the pyrometer stand 502 is coupled to two pyrometers 504A and 504B which may be configured for sensing the temperature at pre-determined locations internal to the reaction chamber and external to the reaction chamber. For example, pyrometer 504A may be configured for sensing the temperature within the reaction chamber and particularly for sensing the temperature of a substrate disposed upon the susceptor within the reaction chamber, whereas pyrometer 504B may be configured for sensing the external temperature of the quartz reaction chamber.

Also disposed on the pyrometer stand 502 are positioning devices 506A and 506B, which may be utilized to enable precise positioning of the associated pyrometers 504A and 504B. As a non-limiting example embodiment, the positioning devices 506A and 506B coupled to the pyrometers 504A and 504B may comprise micrometers that may be configured for positioning and re-positioning the pyrometers 504A and 504B in both the x-axis and the y-axis. Upper heating housing 206 may also comprise one or more pyrometer cooling blocks 508 which are in thermal contact with the pyrometers 504A and 504B and provide a heat sink function to enable cooling of the pyrometers 504A and 504B. The upper heating housing 206 may also include one or more lift lid brackets 510, which may be utilized for raising and lowering the upper heating housing.

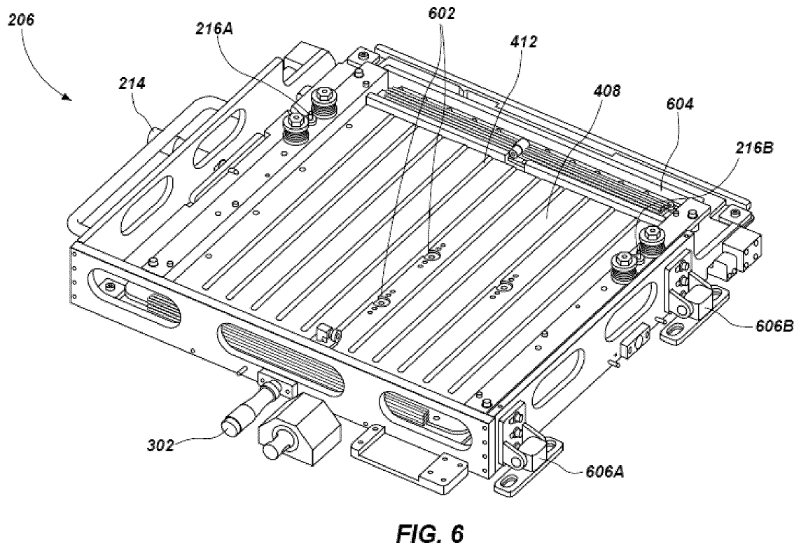

FIG. 6 illustrates the upper heating housing 206 with the upper heating housing wall removed and various other ancillary components removed from within the upper heating housing 206 to enable a view of the functionality of the upper heating housing 206. For example, the interior of upper heating housing 206 may include the single piece reflector 408 disposed above the array of radiant heating elements (not shown), the single piece reflector 408 including air flow openings 412, extending from the upper surface of the single piece reflector and down to the lower surface of the single piece reflector, the plurality of air flow openings 412 utilized for providing cooling to the plurality radiant heating elements and the underlying quartz reaction chamber. The single piece reflector 408 may also include additional openings 602 which again may also extend from the upper surface of the single piece reflector through to the lower surface of the single piece reflector. The additional opening through the single piece reflector may be utilized for directing a light probe through the single piece reflector from the previously discussed pyrometers disposed upon the upper heating housing wall (as shown previously in FIG. 5).

The interior of the upper heating housing 206, as illustrated in FIG. 6, may further comprise an xy-stage 604 which may be coupled to both the single piece reflector 408 (and the associated array of radiant heating elements) and one or more variable positioning devices which, as a non-limiting example, may include a micrometer 214 for adjustment of the positioning of the array of radiant heating elements in the x-axis and may further include micrometer 302 for adjustment of the position of the array of radiant heating elements in the y-axis.

In addition to variable positioning devices 214 and 302, the interior of the upper heating housing 206 may comprise additional variable positioning devices 216A and 216B. In some embodiments of the disclosure, variable positioning devices 216A and 216B may comprise adjustment screws which are coupled to the xy-stage 604 and the single piece reflector 408 (and associated array of radiant heating elements). In non-limiting example embodiments, the adjustment screws may be turned clockwise to increase the distance between the array of radiant heating elements and the upper chamber wall and the susceptor disposed below and conversely the adjustment screws may be turned anti-clockwise to decrease the distance between the array of radiant heating element and the upper chamber wall and the susceptor disposed below. In some embodiments of the disclosure, three separate adjustment screws may be coupled to the xy-stage 604 to position and re-position the array of heating elements in the z-axis, i.e., adjusting the relative height of the array of radiant heating element to the upper chamber wall and particularly to the susceptor disclosed within the reaction chamber. In some embodiments, the adjustment screws may include a ball tip at a lower projection, which may be disposed in v-shaped groove disposed on a upper surface of the xy-stage 604 and that points radially inward to ensure that the single piece reflector center remains at the same position when the assembly expands and contracts during heating and cooling processes.

The upper heating housing 206 may further comprise one or more hinged mechanisms for connecting the upper heating housing to a reaction chamber housing. For example, FIG. 6 illustrates hinged mechanisms 606A and 606B, wherein a first surface of the hinged mechanism 606A and 606B is attached to the upper heating housing 206 and a second surface of the hinged mechanism 606A and 606B may be attached to a reaction chamber housing. Therefore, in some embodiments of the disclosure, the at least one array of heating elements are disposed in an upper heating housing and the upper heating housing is connected to a reaction chamber housing via one or more hinged mechanisms.

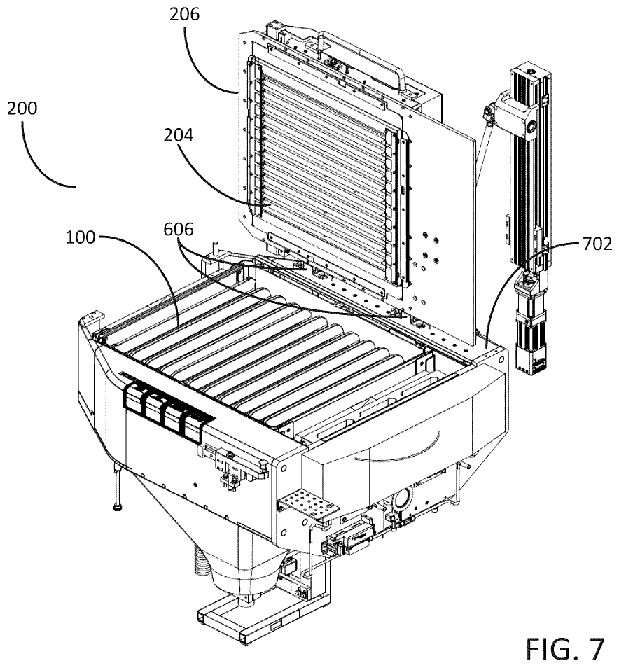

In some embodiments of the disclosure, the one or more hinged mechanisms are connected to the reaction chamber housing in a fixed position, i.e., the coupling between the upper heating housing and the reaction chamber housing is in a fixed, non-variable position, such that any variation in the position of the array of radiant heating elements in the upper heating housing relative to the plurality of ribs comprising the reaction chamber is achieved through adjustment of at least one of the variable positioning devices coupled to the array of heating elements. In other words, the variation in the position of the array of heating elements should not come from the action of raising and lowering of the upper heating housing relative to the reaction chamber. Therefore, in some embodiments, the one or more hinged mechanisms may be configured for raising and lowering the upper heating housing 206 relative to the reaction chamber 100. For example, in some embodiments the one or more hinged mechanism is further configured for repositioning the upper heating housing 206 in a lowered position (i.e., a closed position) with a position tolerance relative to the plurality of ribs of less than 0.25 millimeters. For example, FIG. 7 illustrates the semiconductor processing apparatus 200 of the current disclosure with the upper heating housing 206 in the open position. The upper heating housing includes the upper array of heating elements 204 in the open, i.e., raised position, above the reaction chamber 100 which is disposed in reaction chamber housing 702. As illustrates in FIG. 7, the semiconductor processing apparatus 200 further comprises hinged mechanisms 606 which are utilized to attach the upper heating housing 206 to the reaction chamber housing 702.

The embodiments of the disclosure may also provide methods for calibrating a semiconductor processing apparatus. For example, in some embodiments, the upper array of radiant heating elements may be disposed parallel to the plurality of ribs comprising the quartz reaction chamber and the plurality of ribs may cause a “shadowing” on the substrate disposed within the reaction chamber which may result in areas on the underlying substrate which are at a lower temperature than the average substrate temperature. In addition, the plurality of ribs may cause “light piping” of the radiant energy of the plurality of heating lamps which may result in areas on the underlying substrate which are at a higher temperature than the average substrate temperature. Therefore, the temperature across the substrate disposed on the susceptor may have a characteristic temperature profile which may be dependent on the relative position of the upper array of heating elements and the plurality of ribs. In some embodiments of the disclosure, the characteristic temperature profile may be tuned for a specific process, for example, as a non-limiting example, the temperature profile may be tuned such that a temperature gradient from the substrate edge to the substrate center exists.

During the operation and maintenance of a prior art semiconductor processing apparatus, such as a chemical vapor deposition system utilizing a quartz reaction chamber comprising a plurality of ribs and an upper array of heating elements, it may be necessary to raise the upper heating housing from the closed position, up to the open position and back again. During the operation to raise and lower the upper heating housing, the relative position of the array of heating elements relative to the plurality of ribs comprising the quartz reaction chamber may change and the characteristic temperature profile of the apparatus may be modified. The embodiments of disclosure may therefore provide methods for maintaining the relative position between the plurality of ribs and the upper array of heating elements thereby preserving the characteristic temperature profile of the semiconductor processing apparatus during extended operation and maintenance.

In addition, to enable “tool-to-tool matching” across multiple semiconductor processing apparatuses comprising multiple quartz reaction chambers, the characteristic temperature profile may need to be replicated across multiple semiconductor processing apparatus to ensure that multiple apparatus using the same process recipe produce substantially the same deposition results. Therefore, methods are needed to match the thermal environment of multiple semiconductor processing apparatus.

In some embodiments, a method of calibrating a semiconductor processing apparatus may comprise providing a reaction chamber, the reaction chamber comprising an upper chamber wall and a lower chamber wall connected by vertical side walls, the chamber walls being joined by an upstream inlet flange and a downstream outlet flange wherein the longitudinal direction of the reaction chamber extends from the inlet flange to the outlet flange. The reaction chamber of the methods of the disclosure may also comprise, a plurality of ribs provided on an outer surface of at least the upper chamber wall, the plurality of ribs being orientated transversely to the longitudinal direction of the reaction chamber. The method of calibrating a semiconductor processing apparatus may also comprise, providing at least one array of heating elements disposed above the reaction chamber. In some embodiment the method of calibrating a semiconductor processing apparatus may also comprise, adjusting at least one variable positioning device coupled to the at least one array of heating elements to controllably adjust the position of the array of heating elements relative to the position of the plurality of ribs.

In some embodiments the reaction chamber utilized in the semiconductor process apparatus of the present disclosure may comprise a refurbished reaction chamber, i.e., the reaction chamber may comprise a quartz reaction chamber which has undergone a refurbishment process as described herein. During the process of refurbishing the quartz reaction chamber the critical dimensions of the quartz reaction chamber may be modified, therefore when the refurbished quartz reaction chamber is reutilized within the semiconductor processing apparatus of the current disclosure it may be necessary to adjust the position of the upper array of heating elements relative to the plurality of ribs of the reaction chamber to provide the desired characteristic temperature profile.

In some embodiments the methods may comprise selecting the at least one array of heating elements to comprise a plurality of radiant heating lamps. In some embodiments the plurality of radiant heating lamps are of an elongated tube type disposed substantially parallel to the longitudinal direction of the reaction chamber. In alternative embodiments the plurality of radiant heating lamps are of an elongated tube type disposed substantially perpendicular to the longitudinal direction of the reaction chamber.

The embodiments of the disclosure may comprise methods for maintaining the relative position between an upper array of heating and a plurality of ribs comprising a quartz reaction chamber. Therefore, in some embodiments the methods may comprise selecting at least one variable positioning device to controllably adjust the position of the at least one array of heating elements in a direction substantially parallel to the longitudinal direction of the reaction chamber. In addition, in some embodiments the methods may comprise selecting at least one variable positioning device to controllably adjust the position of the at least one array of heating elements in a direction substantially perpendicular to the longitudinal direction of the reaction chamber. In further embodiments, the methods may comprise selecting the at least one variable positioning device to controllably adjust the height of the at least one array of heating elements relative to the position of the upper chamber wall of the reaction chamber.

In some embodiments of the methods of the disclosure the at least one array of heating elements is coupled to at least two variable positioning devices. For example, the upper array of heating elements may be coupled to a first variable positioning device and a second variable positioning device, wherein the first variable positioning device controllably adjusts the position of the array of heating elements in a direction substantially parallel to the longitudinal direction of the reaction chamber and the second variable positioning device controllably adjust the position of the array of heating elements in a direction substantially perpendicular to the longitudinal direction of the reaction chamber.

In some embodiments of the methods of the disclosure the at least one array of heating elements is coupled to at least three variable positioning devices. For example, the upper array of heating elements may be coupled to a first variable positioning device, a second variable positioning device, and a third variable positioning device, wherein the first and second variable positioning devices may adjust the position of the array of heating elements in the x-y axis and the third variable positioning device may controllably adjust the height of the least at least one array of heating elements relative to the position of the upper chamber wall of the reaction chamber.

In some embodiments the methods may further comprise selecting the at least one variable positioning device to provide a displacement of the at least one array of heating element no greater than approximately 2 centimeters, or no greater than approximately 1 centimeter, or no greater than approximately 0.5 centimeters.

It should be noted that two or more variable positioning devices may be utilized for adjusting the position of the array of heating elements in one particular direction. For example, two or more variable positioning devices may be utilized to controllably adjust the height of the at least one array of heating elements relative to the position of the upper chamber wall of the reaction chamber.

The method of calibrating a semiconductor processing apparatus may further comprise, providing a substrate support disposed within the reaction chamber beneath the at least one array of heating elements, the substrate support configured to support at least one substrate wherein the substrate support has a central axis around which the substrate support rotates. In additional embodiments the methods may comprise providing a single piece reflector comprising a plurality of parabolic segments disposed adjacent to the at least one array of heating elements.

The method of calibrating a semiconductor processing apparatus may further comprise selecting the at least one array of heating elements to be disposed in an upper heating housing and connecting the upper heating housing to a reaction chamber via one or more hinged mechanisms. The method may also comprise selecting the one or more hinged mechanisms to be connected to the reaction chamber housing in a fixed position. The fixed positioning of the one or more hinged mechanism(s) allows the repositioning of upper heating housing by raising and lowering the upper heating housing relative to the reaction chamber, wherein repositioning the upper heating housing comprises repositioning the upper heating housing to a lowered position to a position tolerance relative to the plurality of ribs of less than 0.25 millimeters.

In some embodiments of the disclosure, the reaction chamber may comprise a refurbished quartz reaction chamber and during the refurbishment processes the plurality of ribs comprising the reaction chamber may deviate from a nominal position determined prior to any refurbishment process, i.e., the nominal position of the plurality of ribs is determined for a new, unused reaction chamber. The nominal position of each of the plurality of ribs may be determined by measuring the distance from the inlet flange 110 (see FIG. 2) (or alternatively the outlet flange 112) to each of the plurality of ribs 116. Once the nominal position of each of the plurality of ribs has been determined, the reaction chamber can be utilized until it is determined that the reaction chamber requires a refurbishment process.

Once the refurbishment process on the reaction chamber has been completed, the method of the disclosure may continue by measuring the distance from the inlet flange to each of the plurality of ribs and calculating the deviation distance of each of the plurality of ribs from the previously recorded nominal position. The methods may continue by calculating the average deviation distance for the plurality ribs. The average deviation distance for the plurality of ribs may be recorded on the reaction chamber itself, for example, utilizing an etching process to produce a mark on the reaction chamber, i.e., on the inlet flange. The methods of the disclosure may continue by adjusting the position of the at least one variable positioning device coupled to the at least one array of heating elements by an amount substantially equal to the average deviation distance. Therefore the methods of the disclosure allow for the average deviation distance for the plurality of ribs to be determined and the position of the array of heating elements to be adjusted to compensate for any such average deviation distance of the plurality of ribs.

The methods of calibrating a semiconductor processing apparatus as described herein may reduce the temperature non-uniformity across a substrate disposed within the reaction chamber. For example, in some embodiments the at least one array of heating elements is configured to provide a temperature uniformity difference across the surface of at least one substrate of less than 1.5° C., or a temperature uniformity difference across a surface of the at least one substrate of less than 0.4° C., or even a temperature uniformity difference across a surface of the at least one substrate of less than 0.25° C. In some embodiments the at least one substrate may comprise a substrate with a diameter greater than 25 millimeters, or greater than 100 millimeters, or greater than 200 millimeters, or greater than 300 millimeters, or even greater than 450 millimeters.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A semiconductor processing apparatus comprising:
a reaction chamber comprising:
an upper chamber wall and a lower chamber wall connected by vertical sidewalls, the chamber walls being joined by an upstream inlet flange and a downstream outlet flange wherein a longitudinal direction of the reaction chamber extends from the inlet flange to the outlet flange; and
a plurality of ribs provided on an outer surface of at least the upper chamber wall, the plurality of ribs being orientated transversely to the longitudinal direction of the chamber;
at least one array of heating elements disposed above the reaction chamber; and
at least one variable positioning device coupled to the at least one array of heating elements and configured to controllably adjust a position of the at least one array of heating elements relative to a position of the plurality of ribs.

2. The apparatus of claim 1, wherein the at least one array of heating elements comprises a plurality of radiant heating lamps.

3. The apparatus of claim 2, wherein the plurality of radiant heating lamps are of an elongated tube type disposed substantially parallel to the longitudinal direction of the reaction chamber.

4. The apparatus of claim 2, wherein the plurality of radiant heating lamps are of an elongated tube type disposed substantially perpendicular to the longitudinal direction of the reaction chamber.

5. The apparatus of claim 1, wherein the at least one variable positioning device is configured to controllably adjust the position of the at least one array of heating elements in a direction substantially parallel to the longitudinal direction of the reaction chamber.

6. The apparatus of claim 1, wherein the at least one variable positioning device is configured to controllably adjust the position of the at least one array of heating elements in a direction substantially perpendicular to the longitudinal direction of the reaction chamber.

7. The apparatus of claim 1, wherein the at least one variable positioning device is configured to controllably adjust a height of the at least one array of heating elements relative to a position of the upper chamber wall of the reaction chamber.

8. The apparatus of claim 1, wherein the at least one array of heating elements is coupled to at least two variable positioning devices.

9. The apparatus of claim 1, wherein the at least one array of heating elements is coupled to at least three variable positioning devices.

10. The apparatus of claim 1, further comprising:
a substrate support disposed within the reaction chamber beneath the at least one array of heating elements, the substrate support configured to support at least one substrate; and
wherein the substrate support has a central axis around which the substrate support rotates.

11. The apparatus of claim 10 wherein the at least one array of heating elements is configured to provide a temperature uniformity difference across a surface of the at least one substrate of less than 1.5° C.

12. The apparatus of claim 10 wherein the at least one array of heating elements is configured to provide a temperature uniformity difference across a surface of the at least one substrate of less than 0.4° C.

13. The apparatus of claim 10 wherein the at least one array of heating elements is configured to provide a temperature uniformity difference across a surface of the at least one substrate of less than 0.25° C.

14. The apparatus of claim 1, wherein the at least one variable positioning device is configured to provide a displacement of the at least one array of heating elements no greater than approximately 2 centimeters.

15. The apparatus of claim 1, wherein the reaction chamber comprises a refurbished reaction chamber.

16. The apparatus of claim 1, further comprising a single piece reflector comprising a plurality of parabolic reflectors disposed adjacent to the at least one array of heating elements.

17. The apparatus of claim 1, further comprising an additional array of heating elements disposed beneath the reaction chamber.

18. The apparatus of claim 1, wherein the at least one array of heating elements are disposed in an upper heating housing and the upper heating housing is connected to a reaction chamber housing via one or more hinged mechanisms.

19. The apparatus of claim 18, wherein the one or more hinged mechanisms are connected to the reaction chamber housing in a fixed position.

20. The apparatus of claim 19, wherein the one or more hinged mechanisms are configured for raising and lowering the upper heating housing relative to the reaction chamber; and wherein at least one of the one or more hinged mechanisms is further configured for repositioning the upper heating housing in a lowered position with a position tolerance relative to the plurality of ribs of less than 0.25 millimeters.

21. The apparatus of claim 2, wherein the plurality of radiant heating lamps is of an elongated tube type disposed substantially parallel and adjacent to one another, wherein the distance between the individual radiant heating lamps is adjustable.
